(19) United States
(12) Patent Application Publication
(10) Pub. No.: US 2008/0069669 A1
(43) Pub. Date: Mar. 20, 2008

(54) SUBSTRATE PROCESSING DEVICE, METHOD OF ADJUSTING PRESSURE IN SUBSTRATE PROCESSING DEVICE, AND METHOD OF EXECUTING CHARGE NEUTRALIZATION PROCESSING ON MOUNTING TABLE OF SUBSTRATE PROCESSING DEVICE

(75) Inventors: Keisuke Kondoh, Nirasaki-shi (JP); Hiroshi Koizumi, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTON LIMITED, Tokyo (JP)

(21) Appl. No.: 11/857,271

(22) Filed: Sep. 18, 2007

(30) Foreign Application Priority Data
Sep. 19, 2006 (JP) 2006-252861

(51) Int. Cl. H01L 21/67; B65D 85/86; H01L 21/687

(52) U.S. Cl. 414/217.1; 206/709; 414/220

(57) ABSTRACT

A method adjusts a pressure in a substrate processing device. The substrate processing device has a processing chamber for executing a predetermined processing for a substrate to be processed mounted on a mounting table; a pressure adjustment unit for the processing chamber which adjusts a pressure within the processing chamber; a transfer chamber connected to the processing chamber via a gate valve; and a pressure adjustment unit for the transfer chamber which adjusts a pressure in the transfer chamber and adjusts a pressure within the processing chamber while the gate valve is opened. The method is to adjust a pressure within the processing chamber to a predetermined pressure by using both the pressure adjustment unit for the processing chamber and the pressure adjustment unit for the transfer chamber.

### FIELD OF THE INVENTION

The present invention relates to a substrate processing device including a processing chamber for executing a predetermined processing for a substrate to be processed such as a semiconductor wafer and a Flat Panel Display (FPD) substrate and a transfer chamber connected to the processing chamber via a gate valve, and a method of adjusting a pressure thereof.

### BACKGROUND OF THE INVENTION

For example, a cluster-tool type substrate processing device has a plurality of processing chambers for executing a predetermined processing for a substrate to be processed, for example, a semiconductor wafer (hereinafter, referred to as a “wafer”), and each processing chamber is connected to a common transfer chamber formed in a polygonal shape (for example, a hexagonal shape), while surrounding the chamber, via each gate valve. A transfer device including a transfer arm and so on is provided within the common transfer chamber, and a wafer is loaded to and unloaded from each processing chamber by the transfer device.

For example, when a processing of a wafer terminates in one of the processing chambers, after a gate valve is opened and the processed wafer is unloaded from the processing chamber by the transfer device, an unprocessed wafer is loaded to the processing chamber, and the gate valve is closed and a processing for the unprocessed wafer is started. Accordingly, in order to improve a throughput, a processed wafer within the processing chamber should be replaced with an unprocessed wafer for a time as short as possible.

In each processing chamber, a mounting table for mounting a wafer is disposed, and the mounting table has an electrostatic chuck (ESC) for sustaining a wafer on the mounting table by an electrostatic adsorption force generated by applying a high voltage. In each processing chamber, various processing is executed in a state where a wafer is sustained on the mounting table by electrostatic adsorption.

When a processing of a wafer terminates, by opening the gate valve and turning off a voltage applied to the electrostatic chuck, a wafer processed on the mounting table is removed by the transfer device. Thereafter, before mounting an unprocessed wafer to be processed at a next time on the mounting table, by temporarily raising a pressure within the processing chamber up to a predetermined charge neutralization pressure by operating only a gas supply and exhaust system for the processing chamber side, of a charge neutralization processing for removing a residual charge on the mounting table is executed.

In this way, because a residual charge on the mounting table is removed, when applying a high voltage to the electrostatic chuck, an electrostatic adsorption force can be generated neither more nor less, whereby a wafer can be surely adsorbed and sustained.

However, in a state where a gate valve is opened, when a pressure within a processing chamber is adjusted, a space in which a pressure should be adjusted is extended to within a common transfer chamber as well as within the processing chamber. Accordingly, when a pressure within the processing chamber is adjusted only with a pressure adjustment unit (gas supply and exhaust system) for the processing chamber as in the conventional case, a time required for adjusting a pressure becomes longer. Particularly, in the cluster-tool type substrate processing device, because a common transfer chamber has a capacity (for example, several hundred liters), e.g., 10 times greater than each processing chamber, there is a problem that longer time is required for raising a pressure of the processing chamber up to a charge neutralization pressure when the common transfer chamber is made to communicated therewith.

If a time required for adjusting a pressure within the processing chamber becomes longer, in a state where an unprocessed wafer to be mounted on the mounting table is sustained by a transfer arm, the unprocessed wafer is required to be in a standby state until a charge neutralization processing terminates, whereby a throughput of a wafer processing is decreased.

Accordingly, it is considered to execute pressure adjustment within the processing chamber while the gate valve is closed. However, since pressure within the processing chamber temporarily rises when a charge neutralization processing is executed, if a pressure is adjusted while the gate valve is closed and the gate valve is again opened, dust or particles may be discharged from the processing chamber to the common transfer chamber due to low pressure of the common transfer chamber.

In this case, for example, if a pressure of the processing chamber returns to an original low pressure, and is depressurized to a pressure lower than a pressure of the common transfer chamber and then the gate valve is opened, discharge of dust or particles from the processing chamber to the common transfer chamber may be prevented (see, for example, Japanese Patent Laid-open Application No. 2004-96089). However, in this way, because it takes a time in opening and closing the gate valve or changing again a pressure within the processing chamber, a throughput is decreased.

Further, Japanese Patent Laid-open Application No. 2005-39185 discloses a method of controlling a pressure within a COR processing chamber when a gate valve between a PHT processing chamber and the COR processing chamber is opened. In this method, in order to prevent that an atmosphere in the PHT processing chamber enters the COR processing chamber, a pressure within the COR processing chamber is adjusted by using only a gas exhaust system for the PHT processing chamber. However, as the gate valve between the PHT processing chamber and the COR processing chamber is opened, a capacity of the COR processing chamber is enlarged, whereby it takes time in adjusting a pressure within the COR processing chamber with only a gas exhaust system for the PHT processing chamber, so that a throughput of a wafer processing is decreased.

### SUMMARY OF THE INVENTION

The present invention provides a substrate processing device, a method of adjusting a pressure of the substrate processing device, and a method of performing a charge neutralization processing on a mounting table of the substrate processing device, wherein a pressure of a processing chamber can be adjusted to a predetermined pressure within a short time even if a gate valve is opened between the processing chamber and a transfer chamber so that a throughput can be improved.

In accordance with one aspect of the present invention, there is provided a method adjusts a pressure in a substrate processing device. The substrate processing device has a processing chamber for executing a predetermined processing for a substrate to be processed mounted on a mounting table; a pressure adjustment unit for the processing chamber which adjusts a pressure within the processing chamber; a transfer chamber connected to the processing chamber via a gate valve; and a pressure adjustment unit for the transfer chamber which adjusts a pressure in the transfer chamber and adjusts a pressure within the processing chamber while the gate valve is opened. The method is to adjust a pressure within the processing chamber to a predetermined pressure by using both the pressure adjustment unit for the processing chamber and the pressure adjustment unit for the transfer chamber.

In accordance with another aspect of the present invention, there is provided a substrate processing device including: a processing chamber for executing a predetermined processing for a substrate to be processed mounted on a mounting table; a pressure adjustment unit for the processing chamber which adjusts a pressure within the processing chamber; a transfer chamber connected to the processing chamber via a gate valve and having a transfer device for transferring a substrate to be processed to and from the processing chamber; and a pressure adjustment unit for the transfer chamber which adjusts a pressure within the transfer chamber, wherein while the transfer chamber is made to communicate with the processing chamber by opening the gate valve, a pressure adjustment processing is executed by adjusting a pressure within the processing chamber to a predetermined pressure using both the pressure adjustment unit for the processing chamber and the pressure adjustment unit for the transfer chamber.

In the present invention, when a gate valve is opened to load to and unload from the substrate processing chamber, a capacity is enlarged by communication of the processing chamber with the transfer chamber and thus in this state, it takes time to operate only a pressure adjustment unit for the processing chamber in adjusting a pressure within the processing chamber. However, by actively using a state where the gate valve is opened, a time required for adjusting a pressure within the processing chamber can be shortened. That is, in the present invention, when the gate valve is opened, a pressure adjustment unit for the transfer chamber as well as the pressure adjustment unit for the processing chamber can be used and thus a pressure within the processing chamber can be adjusted using both pressure adjustment units. In accordance with the present invention, pressure adjustment within the processing chamber by the pressure adjustment unit for the processing chamber can be assisted by operating the pressure adjustment unit for the transfer chamber, so that a time required for adjusting a pressure within the processing chamber can be shortened.

Preferably, the mounting table has an electrostatic adsorption unit for holding the substrate to be processed on a surface thereof by an electrostatic adsorption force, and wherein the pressure adjusting includes a charge neutralization processing process for removing a residual charge on the mounting table after the processing for the substrate that is electrostatically adsorbed on the mounting table is completed. In accordance with the present invention, by adjusting a pressure of the processing chamber to a predetermined pressure within a short time, a residual charge on the mounting table can be rapidly removed.

Further, the charge neutralization processing process is executed while a next substrate to be processed is mounted on the mounting table after the processed substrate on the mounting table is removed. In accordance with the present invention, as described above, a time required for executing a charge neutralization processing can be shortened, compared with the conventional case, whereby a charge neutralization processing can be completed for a time period until a next substrate to be processed is mounted on the mounting table after the processed substrate is removed by the transfer device. Accordingly, because it is unnecessary that the transfer device waits with an unprocessed substrate sustained, loading and unloading of a substrate to be processed can be executed, so that a throughput of a substrate to be processed can be improved.

Preferably, the predetermined pressure is in a range from 200 mTorr to 300 mTorr. By adjusting a pressure within the processing chamber to this range, a residual charge on the mounting table can be accurately removed.

It is preferable that the pressure adjustment unit for the transfer chamber has a gas supply system for supplying a predetermined gas into the transfer chamber. A predetermined gas supplied into the transfer chamber by the gas supply system flows into the processing chamber via the gate valve. Therefore, a pressure within the processing chamber can be adjusted to a predetermined pressure. Further, when a flow of the processing gas is formed, discharge of dust or particles from the processing chamber to the transfer chamber is prevented. At this time, as the predetermined gas, inert gas such as N₂ gas is preferably used.

In accordance with still another aspect of the present invention, there is provided a method of performing a charge neutralization processing on the mounting table of a substrate processing device having a processing chamber for executing a predetermined processing for a substrate to be processed mounted on a mounting table; a transfer chamber connected to the processing chamber via a gate valve; a pressure adjustment unit for the processing chamber which adjusts a pressure within the processing chamber; and a pressure adjustment unit for the transfer chamber which adjusts a pressure of the transfer chamber, and executes a charge neutralization processing for the mounting table by temporarily adjusting a pressure within the processing chamber while the gate valve is opened, the method including: temporarily raising a pressure within the processing chamber up to a predetermined neutralization pressure using both the pressure adjustment unit for the processing chamber and the pressure adjustment unit for the transfer chamber.

In accordance with still another aspect of the present invention, there is provided a method of performing a charge neutralization processing on a mounting table of a substrate processing device having a plurality of processing chambers for executing a predetermined processing for a substrate to be processed mounted on the mounting table; a common transfer chamber connected to the processing chambers via respective gate valves; a pressure adjustment unit for the processing chamber provided in each of the processing chambers; and a pressure adjustment unit for the common transfer chamber provided in the common transfer chamber, wherein a charge neutralization processing is executed for the mounting table by temporarily adjusting a pressure within the processing chamber, the method including: temporarily raising a pressure within one of the processing chambers up to a predetermined neutralization pressure using both the pressure adjustment unit for the processing chamber and the pressure adjustment unit for the transfer chamber, when a charge neutralization processing for the mounting table of the processing chamber is executed, in a state where a gate valve between the processing chamber and the common transfer chamber is opened.

Even if a gate valve between a plurality of processing chambers and a common transfer chamber having a large capacity connected thereto is opened, by adjusting a pressure within the processing chamber using both the pressure adjustment unit for the processing chamber and the pressure adjustment unit for the common transfer chamber having pressure adjustment capability much greater than the pressure adjustment unit for the processing chamber, a time required for performing a charge neutralization processing on the mounting table can be shortened.

In accordance with the present invention, even if a gate valve between a processing chamber and a transfer chamber is opened, when adjusting a pressure within the processing chamber to a predetermined pressure by operating a pressure adjustment unit for the processing chamber, pressure adjustment within the processing chamber can be assisted by operating a pressure adjustment unit for the common transfer chamber. Accordingly, a pressure within the processing chamber can be adjusted up to a predetermined pressure within a short time.

### BRIEF DESCRIPTION OF THE DRAWINGS

The objects and features of the present invention will become apparent from the following description of embodiments given in conjunction with the accompanying drawings, in which:

FIG. 1 is a cross sectional view illustrating a configuration of a substrate processing device in accordance with an embodiment of the present invention;

FIG. 2 is a block diagram illustrating a configuration of a controller (system controller) shown in FIG. 1;

FIG. 3 is a block diagram illustrating a configuration of an equipment controller (EC) (device controller) in accordance with an embodiment of the present invention;

FIG. 4 is a block diagram illustrating a configuration of a gas supply and exhaust system of each of a common transfer chamber and a processing chamber in accordance with an embodiment of the present invention;

FIG. 5 is a diagram illustrating an example of an operation timing of units in a charge neutralization processing in accordance with an embodiment of the present invention;

FIG. 6A is a pressure waveform diagram illustrating the change of an internal pressure of a common transfer chamber and a processing chamber when a charge neutralization processing is executed using both a pressure adjustment unit of a processing chamber side and a gas supply system of a common transfer chamber side; and

FIG. 6B is a pressure waveform diagram illustrating the change of an internal pressure of a common transfer chamber and a processing chamber when a charge neutralization processing is executed using only a pressure adjustment unit of a processing chamber side.

### DETAILED DESCRIPTION OF THE EMBODIMENTS

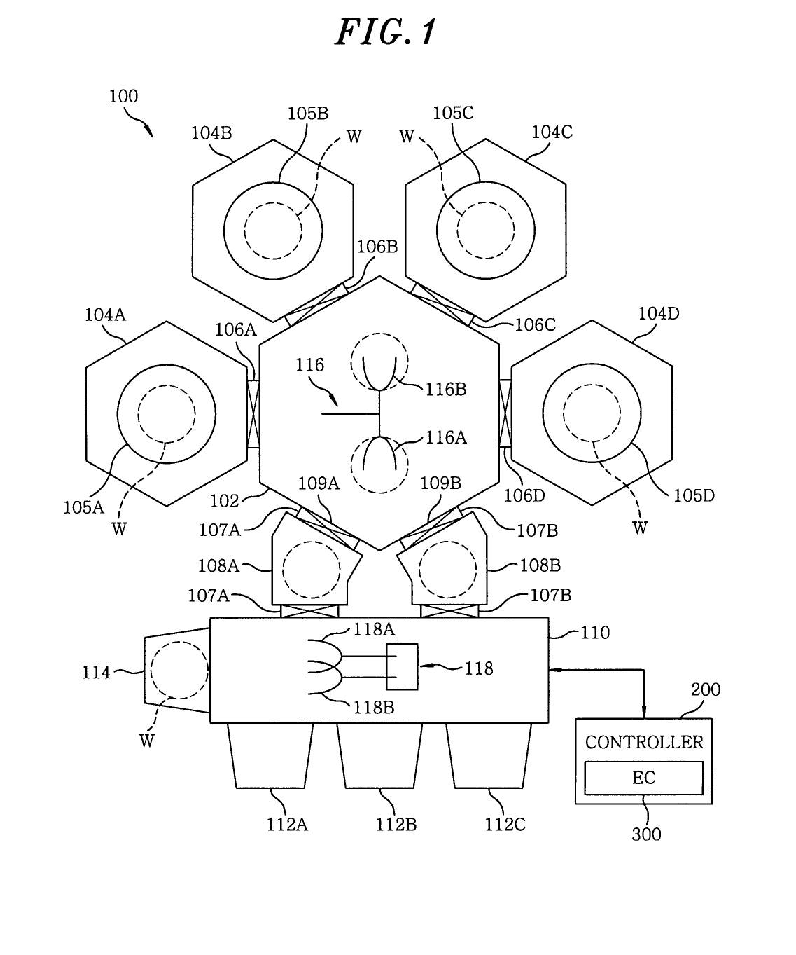

Embodiments of the present invention will now be described with reference to FIGS. 1 to 6B which from a part hereof. Further, like reference numerals designate like elements throughout the specification and thus redundant descriptions thereof will be omitted.

(Example of Configuration of Substrate Processing Device)

An example of a configuration of a substrate processing device in accordance with an embodiment of the present invention will be described with reference to the drawings. FIG. 1 is a cross-sectional view schematically showing a configuration of a substrate processing device in accordance with an embodiment of the present invention. As shown in FIG. 1, a substrate processing device 100 includes a common transfer chamber 102 formed in approximately a polygonal shape (for example, a hexagonal shape), a plurality of (for example, four) processing chambers 104A to 104D configured to be vacuum evacuable, two load lock chambers 108A and 108B configured to be vacuum evacuable, a transfer chamber 110 of a loading side formed in approximately a rectangular shape, a plurality of (for example, three) introduction ports 112A to 112C for mounting a cassette for housing a plurality of wafers W, and an orientor 114 for aligning a position of the wafer W by rotating the wafer W and optically seeking an eccentric amount of the wafer W.

The processing chambers 104A to 104D are connected to the common transfer chamber 102 via respective gate valves 106A to 106D surrounding the common transfer chamber 102. In each of the processing chambers 104A to 104D, mounting tables 105A to 105D for mounting a substrate to be processed, i.e. a semiconductor wafer W are provided. Each of the mounting tables 105A to 105D has an electrostatic chuck as an electrostatically holding unit and can hold a mounted wafer W by the electrostatic chuck. Each of the processing chambers 104A to 104D can executes a predetermined processing for a wafer W mounted on the mounting tables 105A to 105D. Further, the electrostatic chuck and a peripheral configuration thereof will be described later.

Within the common transfer chamber 102, a transfer device 116 having two picks (end effectors) 116A and 116B for holding a wafer W and configured to extend, contract, and rotate is provided. The transfer chamber 110 of the loading side is connected to the common transfer chamber 102 via two loadlock chambers 108A and 108B. The loadlock chamber 108A is connected to the common transfer chamber 102 and the transfer chamber 110 of a loading side via a gate valve 107A and the loadlock chamber 108B is connected to the common transfer chamber 102 and the transfer chamber 110 of a loading side via a gate valve 107B.

Further, a transfer port 109A of a connection part between the common transfer chamber 102 and any one of two loadlock chambers, for example, the loadlock chamber 108A is used as a loading port for exclusively loading a wafer W into the common transfer chamber 102, and a transfer port 109B of a connection part between the common transfer chamber 102 and the other loadlock chamber 108B is used as a unloading port for exclusively unloading a wafer W from the common transfer chamber 102.

For example, three introduction ports 112A to 112C and the orientor 114 are connected to the transfer chamber 110 of the loading side. Further, within the transfer chamber 110 for the loading side, a transfer device 118 having two picks (end effectors) 118A and 118B for sustaining a wafer W and configured to extend, contract, rotate, lift, and linearly move is provided.

A controller 200 is connected to the substrate processing device 100 and controls each unit of the substrate processing device 100.

(Example of Configuration of Controller)

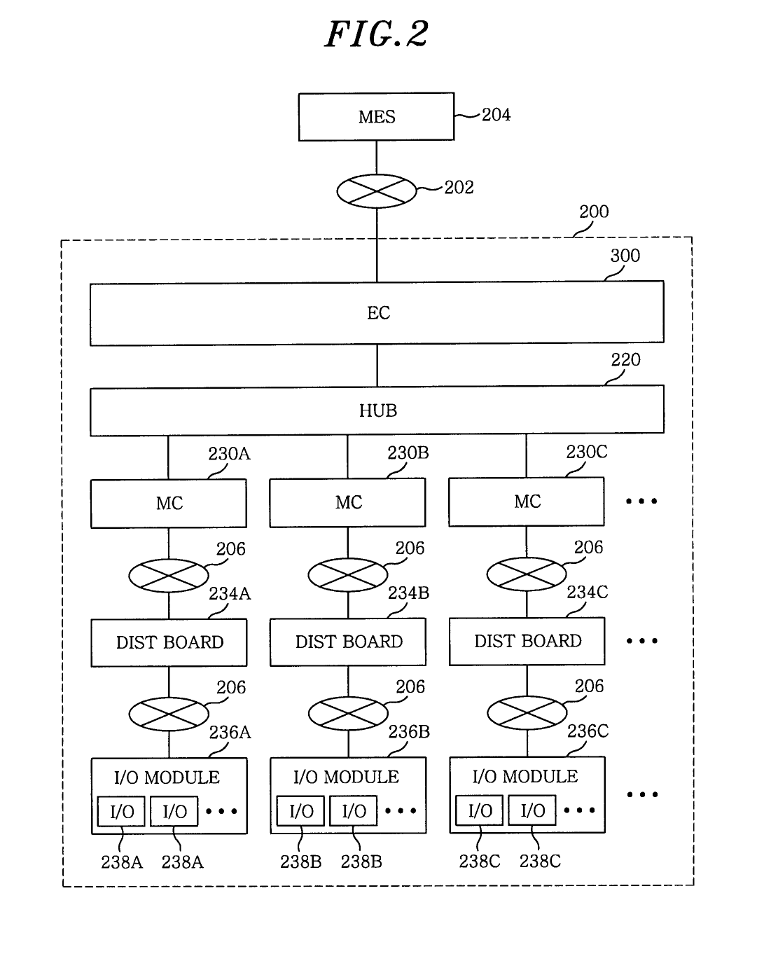

An example of a configuration of the controller 200 of the substrate processing device 100 is described with reference to the drawings. FIG. 2 is a block diagram illustrating a configuration of the controller (system controller) 200. As shown in FIG. 2, the controller 200 includes an equipment controller (EC) 300 and a plurality of module controllers (MC) 230A, 230B, and 230C, and a switching hub 220 for connecting the EC 300 and each of the plurality of MCs 230A, 230B, and 230C.

The controller 200 is connected through the EC 300 to a Manufacturing Execution System (MES) 204 for managing a manufacturing process of an entire factory in which the substrate processing device 100 is provided via, for example, a Local Area Network (LAN) 202. The MES 204 includes, for example, a computer. The MES 204 feeds back real time information about a process in a factory to a main business system (not shown) in connection with the controller 200 and determines a process in consideration of a load of an entire factory.

The EC 300 includes the MCs 230A, 230B, and 230C and constitutes a main controller (master controller) for controlling an entire operation of the substrate processing device 100. The switching hub 220 routes a connection point of the EC 300 to the MC 230A, 230B, and 230C according to a control signal from the EC 300.

Each of the MCs 230A, 230B, and 230C constitutes a sub controller (slave controller) for controlling an operation of modules such as the common transfer chamber 102, the processing chambers 104A to 104D, the loadlock chambers 108A and 108B, the transfer chamber 110, and the orientor 114 of the substrate processing device 100. The MCs 230A, 230B, and 230C is connected to input/output (I/O) modules 236A, 236B, and 236C via, for example, a GHOST network 206 by means of Distribution (DIST) boards 234A, 234B, and 234C, respectively.

The GHOST network 206 is a network realized by large-scale integration (LSI) called a General High-Speed Optimum Scalable Transceiver (GHOST) mounted in the MC board of the EC 300. 31 I/O modules to the maximum can be connected to the GHOST network 206. Further, in the GHOST network 206, the MC corresponds to a master and the I/O module corresponds to a slave.

Each of I/O modules 236A, 236B, and 236C includes a plurality of I/O units 238A, 238B, and 238C connected to each component (hereinafter, referred to as an “end device”) of each module such as processing chambers 104A to 104D and transmits a control signal of each end device and an output signal from each end device. The end device of the processing chamber 104 includes, for example, a mass flow controller for controlling a flow rate of gas introduced into the processing chamber 104, an APC (auto pressure control) valve for controlling exhaust from the processing chamber 104, and a gate valve 106 between the processing chamber 104 and the common transfer chamber 102.

Each GHOST network 206 is connected to an I/O board (not shown) for controlling input and output of a digital signal, an analog signal, and a serial signal in the I/O units 238A, 238B, and 238C.

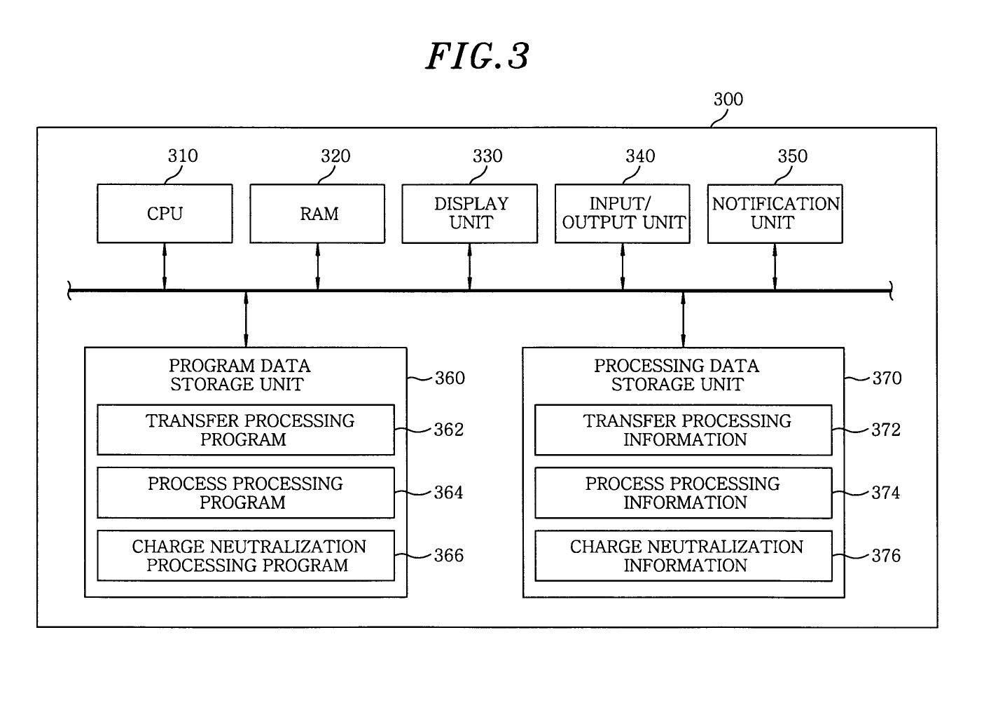

An example of a configuration of the EC 300 shown in FIG. 2 will now be described with reference to the drawings. FIG. 3 is a block diagram illustrating an example of a configuration of the EC 300. As shown in FIG. 3, the EC 300 includes a central processing unit (CPU) 310 forming a main part thereof, a Random Access Memory (RAM) 320 having a memory area used to process various data executed by the CPU 310, a display unit 330 including a liquid crystal monitor for displaying a manipulation screen or a selection screen, an input and output unit 340 for performing input of various data such as input or edition of a processor recipe by an operator and output of various data such as output of a processor recipe or a process log to a predetermined storage medium, and a notification unit 350 such as an alarm (for example, buzzer) for notifying, when an accident such as electric leakage is generated in the substrate processing device 100, the accident.

Further, the EC 300 includes a program data storage unit 360 for storing a processing program for executing various processing of the substrate processing device 100, and a processing data storage unit 370 for storing information (data) required for executing the processing program. The program data storage unit 360 and the processing data storage unit 370 are constructed in a storage area, for example, a hard disk (HDD). The CPU 310 reads necessary program and data from the program data storage unit 360 and the processing data storage unit 370, as needed, and executes various processing programs.

The CPU 310, the RAM 320, the display unit 330, the input and output unit 340, the notification unit 350, the program data storage unit 360, and the processing data storage unit 370 are connected to a bus line such as a control bus and a data bus. The switching hub 220 is also connected to the bus line.

An example of controlling the substrate processing device 100 with the controller 200 having the above-described configuration will now be described. When transfer a wafer W to each of the processing chambers 104A to 104D, the CPU 310 of the EC 300 reads a transfer processing program from a transfer processing program storage area 362 of the program data storage unit 360 and reads transfer processing information from a transfer processing information storage area 372 of the processing data storage unit 370. The CPU 310 executes the transfer processing program based on the transfer processing information. Accordingly, a wafer W is carried to modules such as the common transfer chamber 102, the processing chambers 104A to 104D, the loadlock chambers 108A and 108B, the transfer chamber 110, and the orientor 114 of the substrate processing device 100.

Further, when a process processing such as a cleaning processing, a film forming processing, and an etching processing is performed on a wafer W in each of the processing chambers 104A to 104D, the CPU 310 of the EC 300 reads a processing program executed in a process processing program storage area 364 of the program data storage unit 360 and reads process processing information executed in a process processing information storage area 374 of the processing data storage unit 370. The CPU 310 executes the process processing program based on the process processing information. Accordingly, a predetermined process processing is performed on a wafer W.

However, in each of the processing chambers 104A to 104D of the substrate processing device 100 in accordance with the present embodiment, after a wafer W subjected to a predetermined processing is unloaded, a charge neutralization processing for removing a residual charge on a wafer mounting surface of the mounting tables 105A to 105D is executed. Specifically, by raising a pressure around the mounting tables 105A to 105D up to a predetermined value, a residual charge of the mounting tables 105A to 105D is removed.

When the charge neutralization processing is executed, the CPU 310 of the EC 300 reads a charge neutralization processing program from a charge neutralization processing program storage area 366 of the program data storage unit 360, and reads charge neutralization processing information from a charge neutralization processing information storage area 376 of the processing data storage unit 370. The CPU 310 executes the charge neutralization processing program based on the charge neutralization processing information. Accordingly, because a residual charge of the mounting tables 105A to 105D is removed, an electrostatic adsorption force can be generated neither more nor less by applying a high voltage to an electrostatic chuck. So, a wafer W can be adsorbed and sustained on the mounting tables 105A to 105D. Further, the charge neutralization processing program may be configured as a part of the transfer processing program or the process processing program. Further, the charge neutralization processing information may be included within the transfer processing information or the process processing information.

The CPU 310 transmits a control signal to a desired end device via the switching hub 220, each MC 230 for controlling the processing chambers 104A to 104D, the GHOST network 206, and the I/O unit 238 of the I/O module 236 in accordance with each processing program, thereby executing each processing.

In the controller (system control) 200 shown in FIG. 2, the I/O unit connected to the plurality of end devices is formed in a module, thereby forming an I/O module without directly connecting the end devices to the EC 300. Because the I/O module is connected to the EC 300 via the MC and the switching hub 220, a communication system can be simplified.

Further, since an address of the I/O unit connected to a desired end device and an address of an I/O module including the I/O unit are included in a control signal transmitted by the CPU 310 of the EC 300, the switching hub 220 refers to an address of an I/O module in a control signal and a GHOST of the MC refers to an address of an I/O unit in a control signal, whereby it is unnecessary that the switching hub 220 and the MC 230 inquire a transmitter of a control signal of the CPU 310. Accordingly, a control signal can be smoothly transmitted.

(Example of Configuration of Gas Supply and Exhaust System of Processing Chamber and Common Transfer Chamber)

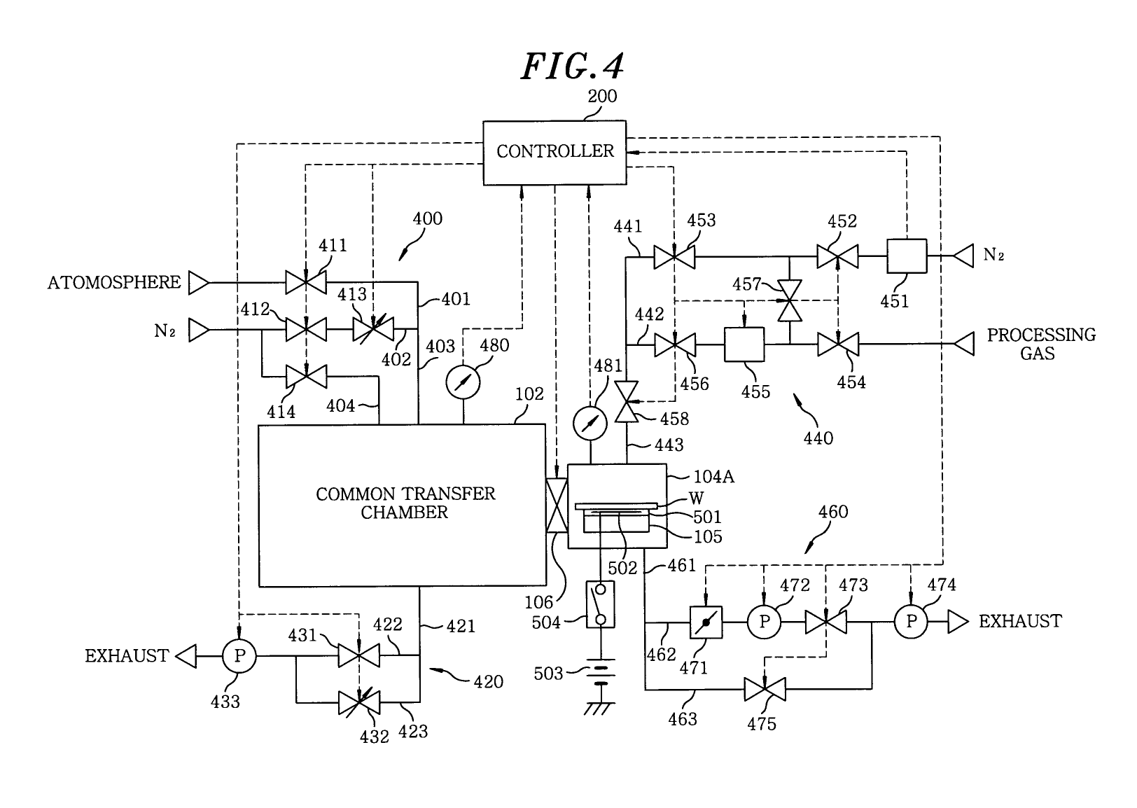

An example of a configuration of a gas supply and exhaust system of the common transfer chamber 102 and each of the processing chambers 104A to 104D in accordance with an embodiment of the present invention will now be described with reference to the drawings. A configuration of the gas supply and exhaust system for each of the processing chambers 104A to 104D is approximately equal to each other and therefore an example of the configuration of a gas supply and exhaust system for the processing chamber 104A is representatively described. FIG. 4 is a block diagram illustrating a configuration of a gas supply and exhaust system of the common transfer chamber 102 and the processing chamber 104.

First, an example of a configuration of a gas supply and exhaust system of the common transfer chamber 102 is described. A gas supply system 400 and a gas exhaust system 420 for the common transfer chamber are connected to the common transfer chamber 102 and thus a flow rate of gas flowing into and out of the common transfer chamber 102 is adjusted, whereby a pressure within the common transfer chamber is controlled. Further, any one or both of the gas supply system 400 and the gas exhaust system 420 for the common transfer chamber can be functioned as a pressure adjustment unit for the processing chamber 104A.

The gas supply system 400 for common transfer chamber includes an atmosphere pipe 401 whose one end is connected to an atmosphere supply source (not shown), a N₂ gas pipe 402 whose one end is connected to an N₂ gas supply source (not shown), a common gas supply pipe 403 whose one end is commonly connected to the other ends of the atmosphere pipe 401 and the N₂ gas pipe 402, the other end thereof being connected to the common transfer chamber 102, and a bypass pipe 404 whose one end is connected to the N₂ gas supply source, the other end thereof being connected to the common transfer chamber 102.

A main gas supply valve 411 is provided in the atmosphere pipe 401, an open-shut valve 412 and a pressure control valve 413 are sequentially provided in the N2 gas pipe 402 from the upstream side, and a bypass valve 414 is provided in the bypass pipe 404. Each of the main gas supply valve 411, the open-shut valve 412, the pressure control valve 413, and the bypass valve 414 is controlled by the controller 200.

In the gas supply system 400 for common transfer chamber having the above-described configuration, by opening the main gas supply valve 411, the inside of the common transfer chamber 102 can be opened to an atmosphere (air purge) via the atmosphere pipe 401 and the common gas supply pipe 403. Further, by adjusting an opening degree of the pressure control valve 413 while opening the open-shut valve 412, a predetermined flow rate of N₂ gas can be introduced into the common transfer chamber 102 via the N₂ gas pipe 402 and the common gas supply pipe 403.

Further, when a so-called non-plasma particle cleaning (NPPC) processing, i.e. a processing of removing particles within the common transfer chamber 102 without forming plasma is executed, by opening the bypass valve 414 and closing the other valves 411 to 413, a large amount of N₂ gas is introduced into the common transfer chamber 102 via the bypass pipe 404. Because a filter is not provided in the bypass pipe 404, the large amount of N₂ gas flows into the common transfer chamber 102, thereby floating particles.

The gas exhaust system 420 for the common transfer chamber includes a common gas exhaust pipe 421 whose one end is connected to the common transfer chamber 102, a first branch gas exhaust pipe 422 whose one end is connected to the other end of the common gas exhaust pipe 421 and whose the other end is connected to a vacuum pump 433, and a second branch gas exhaust pipe 423 disposed in parallel to the first branch gas exhaust pipe 422. A main gas exhaust valve 431 is provided in the first branch gas exhaust pipe 422 and a slow gas exhaust valve 432 is provided in the second branch gas exhaust pipe 423. Each of the main gas exhaust valve 431, the slow gas exhaust valve 432, and the vacuum pump 433 is controlled by the controller 200.

In the gas exhaust system 420 for the common transfer chamber side having the above-described configuration, when the inside of the common transfer chamber 102 is depressurized or the NPPC processing is executed, the main gas exhaust valve 431 is opened and the inside of the common transfer chamber 102 is rapidly exhausted by the vacuum pump 433. In this case, if, due to an excessive exhaust flow rate, two picks 116A and 116B for sustaining a wafer W within the common transfer chamber 102 vibrate for example, it is preferable to close the main gas exhaust valve 431 and slowly exhaust the inside of the common transfer chamber 102 while adjusting an opening degree of the slow gas exhaust valve 432.

Next, an example of a configuration of a gas supply and exhaust system for the processing chamber 104 will be described. A gas supply system 440 and a gas exhaust system 460 for the processing chamber side are connected to the processing chamber 104 and a flow rate of gas flowing into and out of the processing chamber 104 is adjusted thereby, so that a pressure within the processing chamber 104 is controlled. Further, any one or both of the gas supply system 440 and the gas exhaust system 460 for the processing chamber can function as a pressure adjustment unit for the processing chamber.

The gas supply system 440 for the processing chamber includes a N₂ gas pipe 441 whose one end is connected to a N₂ gas supply source (not shown), a processing gas pipe 442 whose one end is connected to the processing gas supply source (not shown), and a common gas supply pipe 443 whose one end is commonly connected to the other ends of the N₂ gas pipe 441 and the processing gas pipe 442, the other end thereof being connected to the processing chamber 104.

A transducer 451, a N₂ gas supply source stop valve 452, and a N₂ gas supply valve 453 are sequentially provided in the N₂ gas pipe 441 from the upstream side. Further, a processing gas supply source stop valve 454, a flow adjustment valve 455 such as a mass flow controller (MFC), and a flow-adjusted gas supply valve 456 are sequentially provided in the processing gas pipe 442 from the upstream side, and a common gas supply valve 458 is provided in the common gas supply pipe 443. Further, a flow path switching valve 457 for guiding N₂ gas to the flow adjustment valve 455 is provided between a downstream side port of the N₂ gas supply source stop valve 452 and an upstream side of the flow adjustment valve 455.

The N₂ gas supply source stop valve 452, the N₂ gas supply valve 453, the processing gas supply source stop valve 454, the flow adjustment valve 455, the flow-adjusted gas supply valve 456, the flow path switching valve 457, and the common gas supply valve 458 are controlled by the controller 200. Further, the transducer 451 measures a pressure within the N₂ gas pipe 441, and sends data corresponding to a measured value to the controller 200.

Further, although in the present embodiment, the gas supply system 440 for the processing chamber is configured to supply one processing gas to the processing chamber 104, it may be configured to supply a plurality of processing gases to the processing chamber 104. In this case, it is preferable to dispose gas supply pipes for the processing gases in parallel to the processing gas pipe 442.

In the gas supply system 440 for the processing chamber having the above-described configuration, by opening the N₂ gas supply source stop valve 452, the N₂ gas supply valve 453, and the common gas supply valve 458, N₂ gas can be introduced into the processing chamber 104 via the N₂ gas pipe 441 and the common gas supply pipe 443. Further, by adjusting a flow rate of processing gas by the flow adjustment valve 455, while opening the processing gas supply source stop valve 454, the flow-adjusted gas supply valve 456, and the common gas supply valve 458, the flow rate of processing gas can be introduced at a predetermined flow rate into the processing chamber 104 via the processing gas pipe 442 and the common gas supply pipe 443.

Further, when it is desired to adjust a flow rate of the N₂ gas introduced into the processing chamber 104, by opening the flow path switching valve 457, N₂ gas is supplied to the processing chamber 104 via the processing gas pipe 442 and the common gas supply pipe 443. When a flow path of N₂ gas is changed, a flow rate of the N₂ gas can be adjusted by the flow adjustment valve 455.

The gas exhaust system 460 for the processing chamber includes a common gas exhaust pipe 461 whose one end is connected to the processing chamber 104, a first branch gas exhaust pipe 462 whose one end is connected to the other end of the common gas exhaust pipe 461 and whose the other end is connected to a dry vacuum pump 474, and a second branch exhaust pipe 463 disposed in parallel to the first branch gas exhaust pipe 462.

The APC valve (also serving as a turbomolecular pump protection valve) 471, a turbomolecular pump 472, and a turbomolecular pump protection valve 473 are provided in the first branch gas exhaust pipe 462, and a rough exhaust valve 475 is provided in the second branch exhaust pipe 463. The APC valve 471, the turbo molecular pump 472, the turbomolecular pump protection valve 473, the roughing valve 475, and the dry vacuum pump 474 are controlled by the controller 200.

In the gas exhaust system 460 for the processing chamber having the above-described configuration, for example, when the inside of the processing chamber 102 is depressurized to an atmospheric pressure, the rough exhaust valve 475 is opened and gas within the processing chamber 104 is exhausted via the common gas exhaust pipe 461 and the second branch exhaust pipe 463 using only the dry vacuum pump 474. Thereafter, when a pressure within the processing chamber 104 is depressurized to some extent, the rough exhaust valve 475 is closed and the turbomolecular pump protection valve 473 is opened, and gas within the processing chamber 104 is exhausted by using the turbomolecular pump 472 while adjusting a gas exhaust pressure with the APC valve 471 until the inside of the processing chamber 104 becomes a predetermined vacuum degree.

In the common transfer chamber 102, a pressure measurement unit 480 for measuring a pressure in the common transfer chamber is provided, and pressure data corresponding to a measured pressure value within the common transfer chamber 102 are sent to the controller 200. Further, in the processing chamber 104, a pressure measurement unit 481 within the processing chamber is provided, and measured pressure data corresponding to a pressure value for measuring a pressure the processing chamber 104 are also sent to the controller 200. The controller 200 controls operation of valves and pumps constituting the gas supply and exhaust system for the common transfer chamber 102 and the gas supply and exhaust system for the processing chamber 104 based on the pressure data. Further, the pressure measurement units 480 may include, for example, a capacitance manometer or a Pirani gage.

Further, an electrostatic chuck 501 is disposed in the mounting table 105 within the processing chamber 104, and a DC power source 503 is connected to an electrode plate 502 of the electrostatic chuck 501. By applying a high voltage from the DC power source 503 to the electrode plate 502 under high vacuum, a wafer W can be electrostatically adsorbed to the electrostatic chuck 501. A switch 504 for turning on and off an applied voltage to the electrostatic chuck 501 is connected between the electrode plate 502 and the DC power source 503.

(Example of Operation of Substrate Processing Device)

An operation of a substrate processing device having the above-described configuration will now be described. The substrate processing device 100 is operated in accordance with an instruction of the CPU 310 of the EC 300 as described above. For example, a wafer W unloaded from any one of cassette containers 112A to 112C by the transfer device 118 is carried to the orientor 114 and a position thereof is determined in the orientor 114. The wafer W whose position is determined is unloaded from the orientor 114 and is loaded into the loadlock chamber 108A or 108B. In this case, when the wafer W subjected to all necessary processing is in the loadlock chamber 108A or 108B, the processed wafer W is unloaded therefrom and then an unprocessed wafer W is loaded thereinto.

The wafer W loaded to the loadlock chamber 108A or 108B is unloaded therefrom by the transfer device 116, and is loaded to the processing chamber 104 where the wafer W is processed, to be mounted on the mounting table 105. When a high voltage is applied to the electrostatic chuck 501 by turning on the switch 504, the wafer W mounted on the mounting table 105 is sustained by an electrostatic adsorption force of the electrostatic chuck 501. In this state, a predetermined processing is performed on the wafer W.

Thereafter, when a predetermined processing for the wafer W is completed, by turning off the switch 504, application of a high voltage to the electrode plate 502 of the electrostatic chuck 501 is turned off and thus an electrostatic adsorption force of the wafer W is released. The processed wafer W is transferred from the transfer device 116 by a transfer unit (not shown) and is unloaded from the processing chamber 104 by the transfer device 116. In this case, when it is necessary to continuously process the wafer W in a plurality of processing chambers 104, the wafer W is loaded to another processing chamber 104 for a next processing, and a processing is executed in the processing chamber 104.

The wafer subjected to all necessary processing is returned to the loadlock chamber 108A or 108B. The processed wafer W returned to the loadlock chamber 108A or 108B are returned to the original cassette container 112A to 112C by the transfer device 118.

In order to improve a throughput of a processing in each processing chamber 104, it is preferable to make a wafer W wait at a position as closer as possible to the processing chamber 104. Accordingly, even while a processing is executed in the processing chamber 104, a wafer W is sequentially unloaded from a cassette container 112 and is in a standby state in the common transfer chamber 102, the loadlock chamber 108A or 108B, and the orientor 114. When a processing of a piece of wafer W is completed in the processing chamber 104, the wafer W is immediately returned to the original cassette container 112, a next wafer W in a standby state in the common transfer chamber 102 is immediately loaded to the processing chamber 104, and other wafers W in a standby state are sequentially advanced.

However, when a wafer W is loaded to the processing chamber 104 by the transfer device 116 to be mounted on the mounting table 105, it is preferable that an electric charge is not remained at the mounting table 105. When no residual charge exists at the mounting table 105, if a high voltage is applied to the electrostatic chuck 501, an electrostatic adsorption force can be generated neither more nor less, and thus a wafer W can be surely adsorbed and sustained. Accordingly, in the substrate processing device 100 in accordance with the present embodiment, by temporarily raising a pressure within a processing chamber up to a predetermined charge neutralization pressure, a residual charge of the mounting table 105 is removed.

(Charge Neutralization Processing for Mounting Table)

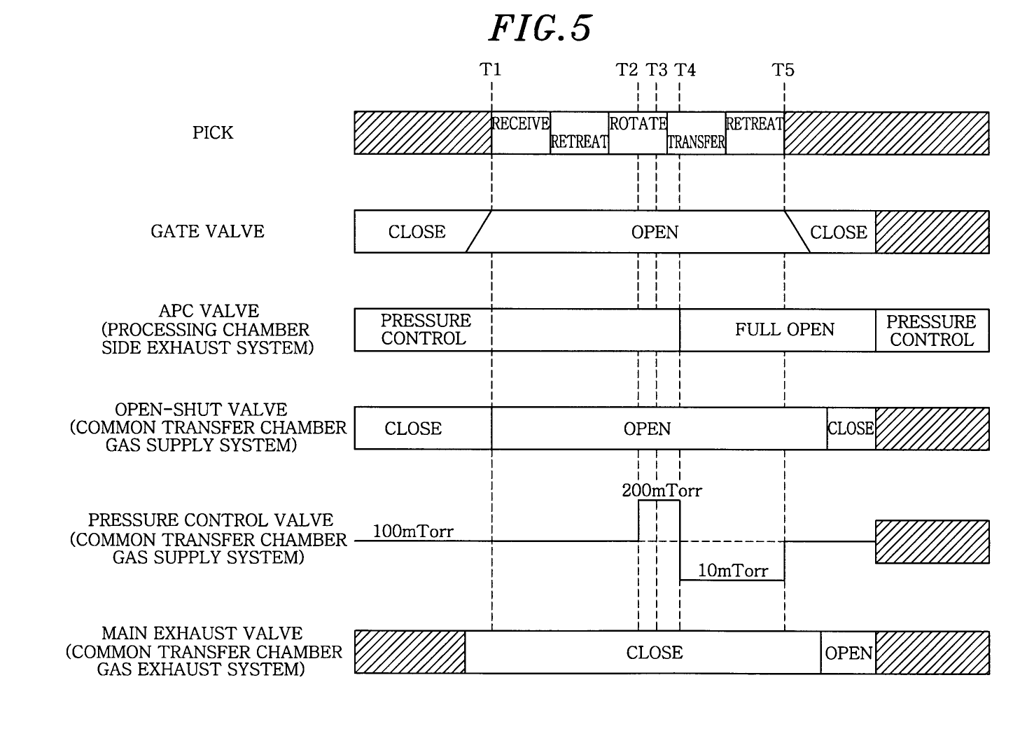

A charge neutralization processing for the mounting table 105 in accordance with the present embodiment will now be described with reference to the drawings together with an example of an operation of the substrate processing device 100. FIG. 5 shows an example of an operation timing of units, for example, the picks 116A and 116B, the gate valve 106, the APC valve 471, the open-shut valve 412, the pressure control valve 413, and the main gas exhaust valve 431 in a charge neutralization processing for the mounting table 105.

After a predetermined processing for a wafer W is executed in the processing chamber 104, the processed wafer W is unloaded from the processing chamber 104 to the common transfer chamber 102 by any one, for example, the pick 116A of two picks 116A and 116B of the transfer device 116 provided within the common transfer chamber 102. Then, an unprocessed wafer W is loaded from the common transfer chamber 102 to the processing chamber 104 by the other pick 116B than the pick 116A used in the unloading operation. The wafer W exchange processing in the processing chamber 104 is executed between a time point T1 and a time point T5.

First, right before the time point T1, the pick 116A and 116B stands by within the common transfer chamber 102. At that time, it is preferable that the pick 116B sustains a next wafer W to be processed within the processing chamber 104.

Further, before the time point T1, because the gate valve 106 is closed, an internal space of the common transfer chamber 102 and an internal space of the processing chamber 104 are in a closed state. Accordingly, in the common transfer chamber 102, by operating the gas supply and exhaust system 400 and 420 for the common transfer chamber, a pressure within the common transfer chamber 102 is adjusted. Further, in the processing chamber 104, by operating the gas supply and exhaust systems 440 and 460 for the processing chamber side, a pressure within the processing chamber 104 is adjusted.

For example, in the processing chamber 104, a flow rate of N₂ gas exhausted from the processing chamber 104 by the gas exhaust system 460 for the processing chamber is controlled by using the APC valve 471 while supplying N₂ gas into the processing chamber 104 at a predetermined flow rate by the gas supply system 440 for the processing chamber, whereby a pressure within the processing chamber 104 is adjusted to, for example, 100 mTorr. In the common transfer chamber 102, while supplying N₂ gas into the common transfer chamber 102 by opening the open-shut valve 412 by the gas supply system 400 for the common transfer chamber and then controlling the pressure control valve 413, the main gas exhaust valve 431 is operated by the gas exhaust system 420 for the common transfer chamber and then the inside of the common transfer chamber 102 is exhausted, whereby a pressure within the common transfer chamber 102 is adjusted to, for example, 100 mTorr.

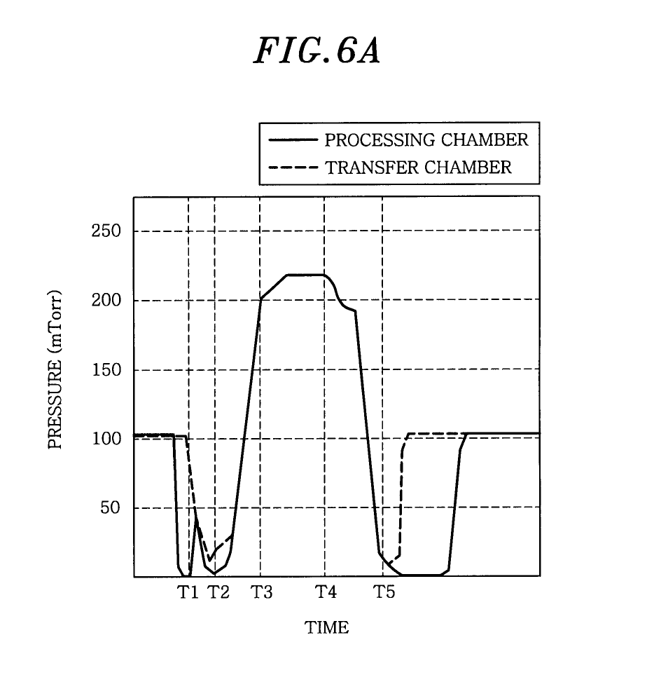

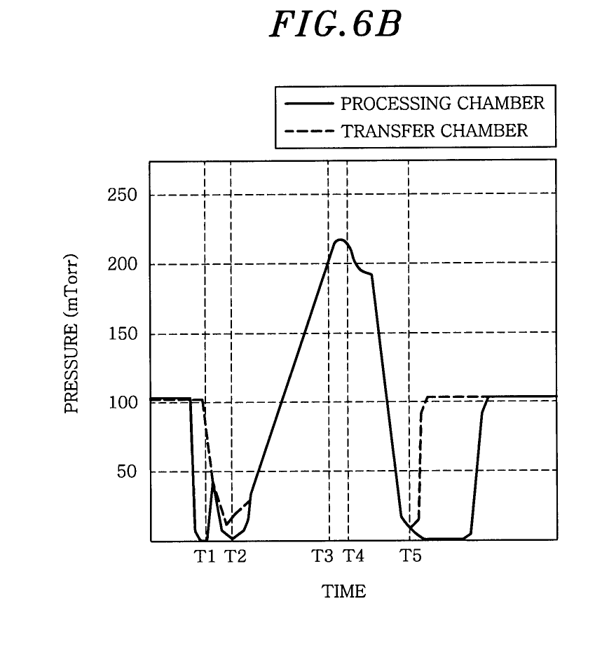

Right before the time point T1, by the APC valve 471, a pressure within the processing chamber 104 is adjusted to be lower than a pressure within the common transfer chamber 102, for example, to several mTorr as shown in FIGS. 6A and 6B. By making a pressure in the processing chamber 104 different from that in the common transfer chamber 102, when the internal space of the common transfer chamber 102 is made to communicate with the internal space of the processing chamber 104 by opening the gate valve 106 at the time point T1, discharge of dust or particles from the processing chamber 104 to the common transfer chamber 102 can be prevented.

Next, in order to exchange wafers W with the transfer device 116, the gate valve 106 is opened at the time point T1. At this time, the internal space of the common transfer chamber 102 communicates with the internal space of the processing chamber 104. Accordingly, the internal pressure of the common transfer chamber 102 is temporarily decreased by an influence of a high vacuum degree within the processing chamber 104, and the internal pressure of the processing chamber 104 rises once by an influence of the pressure in the common transfer chamber 102, and is then decreased again by the control of the APC valve 471.

When the gate valve 106 is opened, the pick 116A is advanced into the processing chamber 104 and receives a processed wafer W from the mounting table 105. The pick 116A, receiving the processed wafer W, is retreated from the processing chamber 104 to the common transfer chamber 102. As the pick 116A sustaining the processed wafer W and the pick 116B sustaining an unprocessed wafer W revolve, the pick 116B instead of the pick 116A faces a wafer unloading and loading port of the processing chamber 104.

Next, at the time point T2, in the processing chamber 104, while N₂ gas is supplied into the processing chamber 104 with a predetermined flow rate by the gas supply system 440 for the processing chamber, a flow rate of N₂ gas exhausted from the processing chamber 104 is controlled by using the APC valve 471 in the gas exhaust system 460 for the processing chamber. At the same time, in the common transfer chamber, by controlling the pressure control valve 413 by the gas supply system 400 for the common transfer chamber, N₂ gas is supplied to the common transfer chamber 102, whereby a pressure within the processing chamber 104 rises up to, for example, a predetermined pressure (charge neutralization pressure: for example, 200 mTorr) for removing a residual charge of the mounting table 105. At this time, because the internal space of the processing chamber 104 communicates with the internal space of the common transfer chamber 102, a pressure within the processing chamber 104 also rapidly rises as shown in FIG. 6A (the time point T2 to a time point T3) in response to pressure rise within the common transfer chamber 102.

By operating the pressure adjustment unit for the common transfer chamber (here, the gas supply system 400 for the common transfer chamber) while operating the pressure adjustment unit for the processing chamber (here, the gas supply system 440 and the gas exhaust system 460 for the processing chamber), pressure adjustment within the processing chamber by the pressure adjustment unit for the processing chamber can be assisted by the pressure adjustment unit for the common transfer chamber.

Further, because N₂ gas is introduced at one time by the gas supply system 400 for the common transfer chamber having gas supply ability higher than the gas supply system 440 processing chamber side, there is generated a flow of gas from the common transfer chamber 102 to the processing chamber 104, and thus discharge of dust or particles from the processing chamber 104 to the common transfer chamber 102 can be prevented. Further, although charge neutralization pressure is not limited to 200 mTorr, it is preferable to set the charge neutralization pressure to a range from 200 mTorr to 300 mTorr in order to efficiently execute a charge neutralization processing for the mounting table 105.

When the internal pressure of the processing chamber 104 reaches 200 mTorr, by keeping the pressure, for example, up to a time point T4, a residual charge of the mounting table 105 can be removed. At the time point T4 at which a residual charge of the mounting table 105 is removed, by fully opening the APC valve 471, a pressure within the processing chamber 104 is depressurized. By controlling the pressure control valve 413 together with the APC valve 471, an amount of N₂ gas flowing into the common transfer chamber 102 is reduced. At this time, a target pressure value within the common transfer chamber 102 is set to, for example, 10 mTorr. Accordingly, as shown in FIG. 6A, in the internal pressure of the processing chamber 104 and the common transfer chamber 102 decrease to several mTorr, so that a charge neutralization processing is completed.

Such a charge neutralization processing is executed together with exchange of a wafer W while exchanging the wafer W by the transfer device 116. Therefore, while the pick 116B sustaining an unprocessed wafer W is advanced into the processing chamber 104 and transfers an unprocessed wafer W to the mounting table 105, the charge neutralization processing for the mounting table 105 is completed. Accordingly, without waiting completion of the charge neutralization processing of the mounting table 105, the exchange processing of a wafer W can be executed.

Next, at a time point T5, after the pick 116B, having transferred an unprocessed wafer to the mounting table 105, is retreated from the processing chamber 104, the gate valve 106 is closed, whereby an exchange processing of a wafer W is completed. Thereafter, pressure adjustment is individually executed in the processing chamber 104 and the common transfer chamber 102. For example, the internal pressure of the processing chamber 104 is adjusted to 100 mTorr by the APC valve 471 and a predetermined processing for an unprocessed wafer W is started. Further, the internal pressure of the common transfer chamber 102 is adjusted, for example, to 100 mTorr by the pressure control valve 413 after closing the open-shut valve 412 and opening the main gas exhaust valve 431.

A pressure waveform obtained by adjusting a pressure within the processing chamber in the charge neutralization processing in accordance with the present embodiment as described above, will be described by comparing with a pressure waveform of a comparative example obtained through pressure adjustment within a processing chamber by a conventional charge neutralization processing. FIG. 6A is a pressure waveform diagram illustrating an example of the change of an internal pressures in the common transfer chamber 102 and the processing chamber 104 when the charge neutralization processing in accordance with the present embodiment, i.e., the charge neutralization processing using both the pressure adjustment units for the common transfer chamber side and the processing chamber is executed. FIG. 6B is a pressure waveform diagram illustrating the change in the internal pressure of the common transfer chamber 102 and the processing chamber 104 when a conventional charge neutralization processing, i.e. a charge neutralization processing using only the pressure adjustment unit for the processing chamber is executed.

FIG. 6A shows a case of raising a pressure within the processing chamber up to the charge neutralization pressure (200 mTorr) by using the gas supply system for the processing chamber and the gas exhaust system for the processing chamber as the pressure adjustment unit for the processing chamber while using the gas supply system for the common transfer chamber as the pressure adjustment unit for the transfer chamber. FIG. 6B shows a case of raising a pressure within the processing chamber up to a charge neutralization pressure (200 mTorr) by using the gas supply system for the processing chamber and the gas exhaust system for the processing chamber as the pressure adjustment unit for the processing chamber without using the pressure adjustment unit for the transfer chamber.

First, in accordance with the comparative example (conventional) pressure waveform shown in FIG. 6B, although the internal pressure of the processing chamber 104, together with the internal pressure of the common transfer chamber 102, slowly rises from a time point (the time point T2) when pressure adjustment is started with only the pressure adjustment unit for the processing chamber, it can be seen that a pressure rising rate thereof is clearly lower than that of FIG. 6A. A time required from the time point T2 to the time point T3 is relatively long, for example, about 14 seconds.

However, in accordance with the pressure waveform of the present embodiment shown in FIG. 6A, the internal pressure of the processing chamber 104 together with the internal pressure of the common transfer chamber 102 rapidly rises from a time point (the time point T2) when pressure adjustment is started using both the pressure adjustment unit for the common transfer chamber and the pressure adjustment unit for the processing chamber. It can be seen that a required time up to a time point T3 at which the pressure reaches 200 mTorr can be shortened to, for example, about 4 seconds corresponding to ⅓ of that in the conventional case.

As described above, in the present embodiment, even if a gate valve between the processing chamber 104 and the common transfer chamber 102 having a large capability is opened, by using both the gas exhaust system 460 for the processing chamber and the gas supply system 400 for the common transfer chamber having gas supply ability higher than the gas exhaust system 460 of the processing chamber, a pressure within the processing chamber 104 is adjusted. Accordingly, because pressure adjustment within the processing chamber by the gas exhaust system 460 for the processing chamber can be assisted by the operation of the gas supply system 400 for the common transfer chamber, a pressure within the processing chamber 104 can rise up to a predetermined charge neutralization pressure that can remove a residual charge of the mounting table 105 even for a very short time.

Further, because a pressure within the processing chamber 104 can be adjusted in a short time, the charge neutralization processing of the mounting table 105 can be completed while removing a processed wafer by the pick 110A from the mounting table 105 and then mounting an unprocessed wafer W by the pick 116B. Accordingly, because it is unnecessary that the transfer device 116 waits while sustaining an unprocessed wafer W, wafer exchange can be smoothly executed and thus a throughput of the substrate processing device 100 can be improved.

In accordance with the present embodiment, the charge neutralization processing for the mounting table 105 starts by raising a pressure within the processing chamber 104 after receiving and revolving a processed wafer from the mounting table 105 within the processing chamber 104. However, the charge neutralization processing may be started earlier. When no wafer exists in the mounting table 105, a charge neutralization processing for the mounting table 105 can be executed. Therefore, a pressure within the processing chamber 104 can be increased, for example, right after a processed wafer is removed from the mounting table 105. Accordingly, a charge neutralization processing can be completed in a shorter time.

Further, in the present embodiment, there has been described a pressure adjustment processing for raising a pressure within the processing chamber 104 up to a charge neutralization pressure. However, the present invention is not limited thereto and can be applied to a pressure adjustment processing for decreasing a pressure within a processing chamber.

Further, in a pressure adjustment processing for a charge neutralization processing in accordance with the present embodiment, there has been described a case of adjusting a pressure within the processing chamber 104 by using the gas supply system 440 and the gas exhaust system 460 for the processing chamber as the pressure adjustment unit for the processing chamber and the gas supply system 400 for the common transfer chamber as the pressure adjustment unit for the common transfer chamber. However, the present invention is not limited thereto. As a pressure adjustment unit for the processing chamber, for example, only the gas supply system 440 for the processing chamber may be used and only the gas exhaust system 460 the processing chamber may be used.

Furthermore, in a pressure adjustment processing for a charge neutralization processing in accordance with the present embodiment, there has been described a case of closing the main gas exhaust valve 431 using only the gas supply system 400 for the common transfer chamber as the pressure adjustment unit for the common transfer chamber side. However, the present invention is not limited thereto. The pressure adjustment may be performed using both the gas supply system 400 and the gas exhaust system 420 for the common transfer chamber.

The present invention may be applied to a system consisting of a plurality of appliances and may be applied to a device including a plurality of equipments or single equipment. A medium such as a storage medium for storing a software program realizing a function of the above-described embodiment is provided to the system or the device so that the present invention can be achieved by enabling a computer (or CPU or MPU) of the system or the device to read and execute the program stored in the medium such as the storage medium.

In this case, because a program itself read from the medium such as the storage medium realizes a function of the above-described embodiment, the present invention includes the medium such as the storage medium storing the program. The medium such as the storage medium for supplying the program includes, for example, a floppy® disk, hard disk, optical disk, optical magnetic disk, CD-ROM, CD-R, CD-RW, DVD-ROM, DVD-RAM, DVD-RW, DVD+RW, magnetic tape, non-volatile memory card, ROM, and network storage.

Further, the present invention includes not only a case of realizing a function of the above-described embodiment by executing a program read by a computer, based on an instruction of the program, but also a case of executing a part or all of an actual processing by an operating system (OS) operating in a computer and then realizing a function of the above-described embodiment by the processing.

Furthermore, a program read from a medium such as a storage medium is written in a memory provided in a function expansion board inserted into a computer or a function expansion unit connected to a computer, and then a CPU provided in a function expansion board or a function expansion unit executes a part or all of an actual processing based on an instruction of the program. The present invention also includes a case of realizing a function of the above-described embodiment by the processing.

The present invention can be applied to a substrate processing device, a method of adjusting a pressure of the substrate processing device, and a method of performing a charge neutralization processing on a mounting table of the substrate processing device.

While the invention has been shown and described with respect to the embodiments, it will be understood by those skilled in the art that various changes and modifications may be made without departing from the scope of the invention.

What is claimed is:

1. A method of adjusting a pressure in a substrate processing device having a processing chamber for executing a predetermined processing for a substrate to be processed mounted on a mounting table; a pressure adjustment unit for the processing chamber which adjusts a pressure within the processing chamber; a transfer chamber connected to the processing chamber via a gate valve; and a pressure adjustment unit for the transfer chamber which adjusts a pressure in the transfer chamber and adjusts a pressure within the processing chamber while the gate valve is opened, the method comprising:
adjusting a pressure within the processing chamber to a predetermined pressure by using both the pressure adjustment unit for the processing chamber and the pressure adjustment unit for the transfer chamber.

2. The method of claim 1, wherein the mounting table has an electrostatic adsorption unit for holding the substrate to be processed on a surface thereof by an electrostatic adsorption force, and
wherein the pressure adjusting includes a charge neutralization processing process for removing a residual charge on the mounting table after the processing for the substrate that is electrostatically adsorbed on the mounting table is completed.

3. The method of claim 2, wherein the charge neutralization processing process is executed while a next substrate to be processed is mounted on the mounting table after the processed substrate on the mounting table is removed.

4. The method of claim 2, wherein the predetermined pressure is in a range from 200 mTorr to 300 mTorr.

5. The method of claim 3, wherein the predetermined pressure is in a range from 200 mTorr to 300 mTorr.

6. The method of claim 1, wherein the pressure adjustment unit for the transfer chamber has a gas supply system for supplying a predetermined gas into the transfer chamber.

7. The method of claim 6, wherein the predetermined gas is N₂ gas.

8. A substrate processing device comprising:
a processing chamber for executing a predetermined processing for a substrate to be processed mounted on a mounting table;
a pressure adjustment unit for the processing chamber which adjusts a pressure within the processing chamber;
a transfer chamber connected to the processing chamber via a gate valve and having a transfer device for transferring a substrate to be processed to and from the processing chamber; and
a pressure adjustment unit for the transfer chamber which adjusts a pressure within the transfer chamber,
wherein while the transfer chamber is made to communicate with the processing chamber by opening the gate valve, a pressure adjustment processing is executed by adjusting a pressure within the processing chamber to a predetermined pressure using both the pressure adjustment unit for the processing chamber and the pressure adjustment unit for the transfer chamber.

9. The substrate processing device of claim 8, wherein the mounting table has an electrostatic adsorption unit for holding the substrate to be processed on a surface thereof by an electrostatic adsorption force, and
the pressure adjustment processing includes a charge neutralization processing for removing a residual charge on the mounting table after the processing for the substrate that is electrostatically adsorbed on the mounting table is completed.

10. The substrate processing device of claim 9, wherein the charge neutralization processing is executed while a next substrate to be processed is mounted on the mounting table after the processed substrate on the mounting table is removed by the transfer device.

11. The substrate processing device of claim 9, wherein the predetermined pressure is in a range from 200 mTorr to 300 mTorr.

12. The substrate processing device of claim 10, wherein the predetermined pressure is in a range from 200 mTorr to 300 mTorr.

13. The substrate processing device of claim 8, wherein the pressure adjustment unit for the transfer chamber has a gas supply system for supplying a predetermined gas into the transfer chamber.

14. The substrate processing device of claim 8, wherein the predetermined gas is N₂ gas.

15. A method of performing a charge neutralization processing on the mounting table of a substrate processing device having a processing chamber for executing a predetermined processing for a substrate to be processed mounted on a mounting table; a transfer chamber connected to the processing chamber via a gate valve; a pressure adjustment unit for the processing chamber which adjusts a pressure within the processing chamber; and a pressure adjustment unit for the transfer chamber which adjusts a pressure of the transfer chamber, and executes a charge neutralization processing for the mounting table by temporarily adjusting a pressure within the processing chamber while the gate valve is opened, the method comprising:
temporarily raising a pressure within the processing chamber up to a predetermined neutralization pressure using both the pressure adjustment unit for the processing chamber and the pressure adjustment unit for the transfer chamber.

16. A method of performing a charge neutralization processing on a mounting table of a substrate processing device having a plurality of processing chambers for executing a predetermined processing for a substrate to be processed mounted on the mounting table; a common transfer chamber connected to the processing chambers via respective gate valves; a pressure adjustment unit for the processing chamber provided in each of the processing chambers; and a pressure adjustment unit for the common transfer chamber provided in the common transfer chamber, wherein a charge neutralization processing is executed for the mounting table by temporarily adjusting a pressure within the processing chamber, the method comprising:
temporarily raising a pressure within one of the processing chambers up to a predetermined neutralization pressure using both the pressure adjustment unit for the processing chamber and the pressure adjustment unit for the transfer chamber, when a charge neutralization processing for the mounting table of the processing chamber is executed, in a state where a gate valve between the processing chamber and the common transfer chamber is opened.
